(19) United States
(12) Patent Application Publication
(10) Pub. No.: US 2022/0140027 A1
(43) Pub. Date: May 5, 2022

(54) DISPLAY DEVICE

(71) Applicant: Samsung Display Co., LTD., Yongin-si (KR)

(72) Inventors: Yong Chan JEON, Cheonan-si (KR); Hyun-Been HWANG, Suwon-si (KR); Da Som GU, Asan-si (KR); Chul Ho JEONG, Seoul (KR)

(73) Assignee: Samsung Display Co., LTD., Yongin-si (KR)

(21) Appl. No.: 17/388,727

(22) Filed: Jul. 29, 2021

(30) Foreign Application Priority Data
Nov. 5, 2020 (KR) 10-2020-0146957

(51) Int. Cl. H01L 27/32; H01L 51/52

(52) U.S. Cl. CPC H01L 27/3248; H01L 51/5253; H01L 51/5284

(57) ABSTRACT

A display device includes a substrate, a transistor disposed on the substrate, a pixel electrode electrically connected to the transistor, an emission layer disposed on the pixel electrode, a common electrode disposed on the emission layer, and a light blocking member disposed on the common electrode. The light blocking member overlaps the entire emission layer.

### CROSS-REFERENCE TO RELATED APPLICATION(S)

This application claims priority to and the benefit of Korean Patent Application No. 10-2020-0146957 under 35 U.S.C. § 119, filed on Nov. 5, 2020 in the Korean Intellectual Property Office, the entire contents of which are incorporated herein by reference.

### BACKGROUND

### 1. Field

The disclosure relates to a display device.

### 2. Description of the Related Art

A display device is a device that displays an image on a screen, and includes a liquid crystal display (LCD), an organic light emitting diode (OLED) display, or the like. Such display devices are used in various electronic devices such as portable telephones, navigation devices, digital cameras, electronic books, portable game devices, or various terminals.

Since the OLED display has a self-luminance characteristic, and unlike the liquid crystal display, it does not require a separate light source, and accordingly it may have reduced thickness and weight. The OLED displays have useful characteristics such as low power consumption, high luminance, and fast response speed.

On the other hand, external light incident on the OLED display may be reflected by some layers of the OLED display and be visible. Thus, the contrast ratio may decrease. The OLED display may be equipped with an anti-reflection portion to prevent deterioration of the contrast ratio due to external light, thereby improving visibility. For example, external light may be prevented from being reflected by attaching a polarization film to the OLED display. However, when using such a polarization film, there is a problem that transmittance is lowered, and power consumption increases to improve luminance. Another problem is that adherence decreases due to the method of attaching the film.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments are to provide a display device capable of increasing a contrast ratio and reducing power consumption by preventing external light from being reflected by the display device, and thus preventing such light from being visible, without using a polarization film.

A display device according to an embodiment may include a transistor disposed on a substrate, a pixel electrode electrically connected to the transistor, an emission layer disposed on the pixel electrode, a common electrode disposed on the emission layer, and a light blocking member disposed on the common electrode. The light blocking member may overlap the entire emission layer.

The light blocking member may be disposed on an entire area of the substrate.

The light blocking member may overlap the pixel electrode.

The display device according to the embodiment may further include an encapsulation layer disposed on the common electrode, and a detection electrode disposed on the encapsulation layer.

The light blocking member may be disposed on the detection electrode, and the light blocking member may overlap the detection electrode.

The light blocking member may be disposed between the common electrode and the encapsulation layer, and the light blocking member may overlap the detection electrode.

The light blocking member may be disposed in the encapsulation layer.

The encapsulation layer may include a plurality of layers, and the light blocking member may be disposed between the plurality of layers of the encapsulation layer.

The light blocking member may be disposed between the encapsulation layer and the detection electrode.

The light blocking member may include a first light blocking portion having a first thickness, and a second light blocking portion having a second thickness. The first thickness may be greater than the second thickness.

The display device may include a plurality of pixels, the first light blocking portion may overlap a boundary of the plurality of pixels, and the second light blocking portion may overlap the plurality of pixels.

The first light blocking portion may not overlap the emission layer, and the second light blocking portion may overlap the emission layer.

The display device according to the embodiment may further include an encapsulation layer disposed on the common electrode, and a detection electrode disposed on the encapsulation layer.

The light blocking member may be disposed on the detection electrode, the first light blocking portion may overlap the detection electrode, and the second light blocking portion may overlap the pixel electrode.

Each of the first light blocking portion and the second light blocking portion of the light blocking member may be formed of a single layer, and the first light blocking portion and the second light blocking portion may be formed by using a mask.

The first light blocking portion of the light blocking member may be formed as multiple layers, and the second light blocking portion of the light blocking member may be formed as a single layer.

The light blocking member may be disposed between the common electrode and the encapsulation layer, the first light blocking portion may overlap the detection electrode, and the second light blocking portion may overlap the pixel electrode.

The light blocking member may include a first light blocking layer, and a second light blocking layer disposed on the first light blocking layer.

A concentration of the second light blocking layer may be higher than a concentration of the first light blocking layer.

The first light blocking layer may be disposed on an entire area of the substrate, and the second light blocking layer may not overlap the emission layer.

According to the embodiments, the contrast ratio of a display device may increase, and power consumption may decrease by preventing external light from being reflected by a display device, and thus prevent such external light from being visible, without using a polarization film.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment.

FIG. 2 is a schematic plan view of a portion including a detection portion in the display device according to the embodiment.

FIG. 3 is a schematic cross-sectional view of a portion of the display area in the display device according to the embodiment.

FIG. 4 is a graph illustrating transmittance of the display device according to an optical density of the light blocking member.

FIG. 5 is a schematic cross-sectional view of a display device according to an embodiment.

FIG. 6 is a schematic cross-sectional view of a display device according to an embodiment.

FIG. 7 is a schematic cross-sectional view of a display device according to an embodiment.

FIG. 8 is a schematic cross-sectional view of a display device according to an embodiment.

FIG. 9 is a schematic cross-sectional view of a display device according to an embodiment.

FIG. 10 and FIG. 11 show schematic cross-sectional views illustrating a method for forming a light blocking member of a display device according to an embodiment.

FIG. 12 and FIG. 13 are schematic cross-sectional views illustrating a method for forming the light blocking member of the display device according to the embodiment.

FIG. 14 is a schematic cross-sectional view of a display device according to an embodiment.

FIG. 15 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

The drawings and description are to be regarded as illustrative in nature and not restrictive. Like reference numerals designate like elements throughout the specification.

In the drawings, size and thickness of each element are arbitrarily illustrated for convenience of description, and the embodiment is not necessarily limited to as illustrated in the drawings. In the drawings, the thickness of layers, films, panels, regions, etc., are exaggerated for clarity. In the drawings, for better understanding and ease of description, the thicknesses of some layers and regions are exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

Unless explicitly described to the contrary, the word “comprise,” and variations such as “comprises” or “comprising,” will be understood to imply the inclusion of stated elements but not the exclusion of any other elements.

Further, throughout the specification, the phrase “in a plan view” means viewing a target portion from the top, and the phrase “in a schematic cross-sectional view” means viewing a cross-section formed by vertically cutting a target portion from the side.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that when an element (or a region, a layer, a portion, or the like) is referred to as “being on”, “connected to” or “coupled to” another element in the specification, it can be directly disposed on, connected, or coupled to another element mentioned above, or intervening elements may be disposed therebetween.

It will be understood that the terms “connected to” or “coupled to” may include a physical or electrical connection or coupling.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

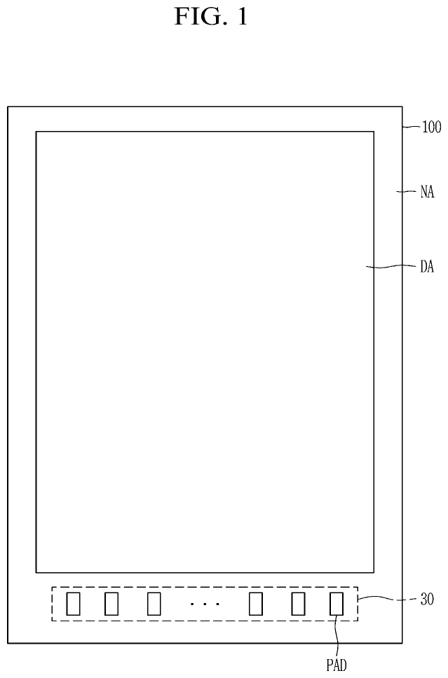

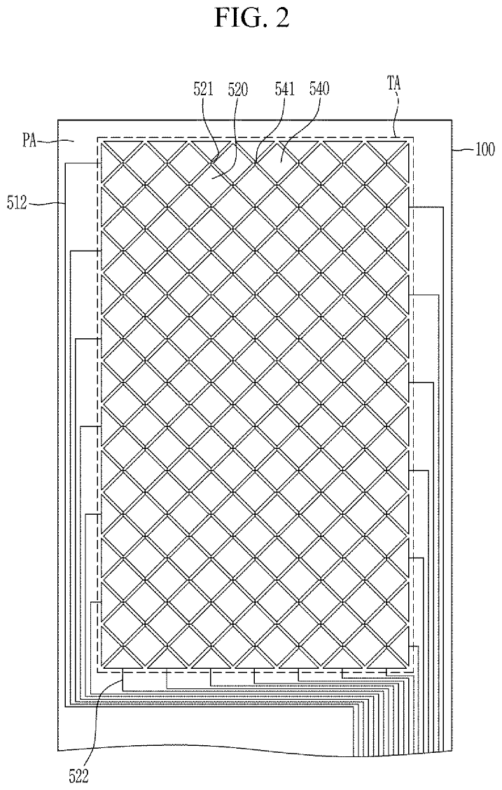

Hereinafter, referring to FIG. 1 and FIG. 2, a display device according to an embodiment will be described.

FIG. 1 is a schematic plan view of a display device according to an embodiment, and FIG. 2 is a schematic plan view of a portion including a detection portion in the display device according to the embodiment.

As shown in FIG. 1, a display device according to an embodiment includes a substrate 100 and a pad portion 30.

The substrate 100 includes a display area DA and a non-display area NA. The display area DA is an area where pixels including light emitting diodes and transistors are formed to display an image, and the non-display area NA is an area where an image is not displayed. The non-display area NA may surround the display area DA. The non-display area NA is an area that includes the pad portion 30 where a pad PAD that applies a driving signal to the pixel is formed.

Pixels (not shown), each including a transistor, a light emitting diode, or the like may be disposed in the display area DA. The pixels may be arranged in various formats, and for example, they may be arranged in a matrix format. A detection area TA that includes detection electrodes 520 and 540 (refer to FIG. 2) may be further disposed to recognize a touch in an upper portion (for example, on the upper surface) of the display area DA.

In the non-display area NA, a driving voltage line (not shown), a driving low-voltage line (not shown), and the pad portion 30 may be disposed to transmit a driving signal such as a voltage, a signal, and the like to the pixel formed in the display area DA. Detection wires 512 and 522 (refer to FIG. 2) may be disposed in the non-display area NA. The detection wires 512 and 522 may be electrically connected to detection electrodes 520 and 540. The detection wires 512 and 522 and the detection electrodes 520 and 540 will be described in further detail with reference to FIG. 2.

The pad portion 30 may be disposed in a portion of the non-display area NA, and includes a pads PAD. A voltage, a signal, and the like may be applied to voltage lines (not shown) and the detection wires 512, and 522 (refer to FIG. 2) electrically connected to the display area DA through pads PAD. A flexible printed circuit board (FPCB) may be attached to the non-display area NA. The flexible printed circuit board may be electrically connected with the pad portion 30. The flexible printed circuit board and the pad portion 30 may be electrically connected with each other by an anisotropic conductive film. The flexible printed circuit board may include a driving integrated circuit (IC) (not shown), and a driving signal output from the driving IC may be supplied to each pixel through each of the pads PAD in the pad portion 30.

As shown in FIG. 2, the substrate 100 further includes a detection area TA where the detection electrodes 520 and 540 are formed, and a peripheral area PA that surrounds the detection area TA in the upper portion of the display area DA. Depending on the embodiments, the detection region TA may include the display area DA and a part of the non-display area NA of FIG. 1, and the peripheral area PA may include areas excluding the detection area TA in the non-display area NA. However, this is only an example, and the embodiments are not limited to the positions of the detection area TA and the peripheral area PA. For example, the detection area TA may include a part of the display area DA, and the peripheral area PA may include an area excluding the detection area TA in the display area DA, and the non-display area NA. In other embodiments, the detection area TA may include the display area DA and the non-display area NA.

The detection area TA may include detection electrodes 520 and 540. The detection electrodes 520 and 540 may include first detection electrodes 520 and second detection electrodes 540.

The first detection electrode 520 and the second detection electrode 540 may be electrically separated from each other. Depending on the embodiments, the first detection electrode 520 may be a detection input electrode, and the second detection electrode 540 may be a detection output electrode. However, the embodiments are not limited thereto, and the first detection electrode 520 may be a detection output electrode, and the second detection electrode 540 may be a detection input electrode.

The first detection electrodes 520 and the second detection electrodes 540 may be alternately distributed so as to not overlap each other in the detection area TA, and may be arranged in a mesh format. The first detection electrodes 520 may be disposed in plural in a column direction and a row direction, and the second detection electrodes 540 may be disposed in plural in a column direction and a row direction. The first detection electrodes 520 may be electrically connected with each other in a column direction by a first detection electrode connection portions 521, and the second detection electrodes 540 may be electrically connected with each other in a row direction by a second detection electrode connection portions 541.

The first detection electrode 520 and the second detection electrode 540 may be disposed on the same layer. Depending on the embodiments, the first detection electrode 520 and the second detection electrode 540 may be disposed in different layers. The first detection electrode 520 and the second detection electrode 540 may be formed in the shape of a rhombus, but are not limited thereto. The first detection electrode 520 and the second detection electrode 540 may have polygonal shapes such a quadrangle and a hexagon, a circular shape, or elliptical shape, and may be implemented in various shapes such as having a protruding portion to improve the sensitivity of the sensing sensor. The first detection electrode 520 and the second detection electrode 540 may be formed of a transparent conductor or an opaque conductor. For example, the first detection electrode 520 and the second detection electrode 540 may include a transparent conductive oxide (TCO), and the transparent conductive oxide may include at least one of an indium-tin oxide (ITO), an indium-zinc oxide (IZO), zinc oxide (ZnO), carbon nanotubes (CNT), and graphene. The first detection electrode 520 and the second detection electrode 540 may include openings. The openings formed in the detection electrodes 520 and 540 allow light emitted from the light emitting diode to be emitted to the front without interference.

The first detection electrodes 520 may be electrically connected with each other by a first detection electrode connection portion (also called a bridge) 521, and the second detection electrodes 540 may be electrically connected with each other by a second detection electrode connection portion 541. When the first detection electrodes 520 are connected in the first direction, the second detection electrodes 540 may be connected in a second direction that crosses the first direction. When the first detection electrode 520 and the second detection electrode 540 are disposed on the same layer, one of the first detection electrode connection portion 521 and the second detection electrode connection portion 541 may be disposed on the same layer as the first detection electrode 520 and the second detection electrode 540, and the other may be disposed in a layer that is different from that of the first detection electrode 520 and the second detection electrode 540. Accordingly, the first detection electrodes 520 and the second detection electrodes 540 may be electrically separated from each other. A detection electrode connection portion disposed in a different layer may be disposed above or below the first detection electrode 520 and the second detection electrode 540, and in the following embodiment, it will be described that the detection electrode connection portion is disposed at a lower layer, in a layer closer to the substrate.

Detection wires 512 and 522 that are respectively connected with the first detection electrodes 520 and the second detection electrodes 540 are disposed in the peripheral area PA. The detection wires 512 and 522 may include first detection wires 512 and second detection wires 522. The first detection wire 512 may be connected with the second detection electrodes 540 arranged in a row direction, and the second detection wire 522 may be connected with the first detection electrodes 520 arranged in a column direction. Depending on the embodiments, the first detection wire 512 and the second detection wire 522 may be electrically connected with a part of the pad PAD included in the pad portion 30 of FIG. 1.

In FIG. 2, a mutual-cap type of detection portion that detects a touch by using two detection electrodes 520 and 540 is illustrated. However, depending on embodiments, the detection portion may be formed as a self-cap type of detection portion that detects a touch by using only one detection electrode.

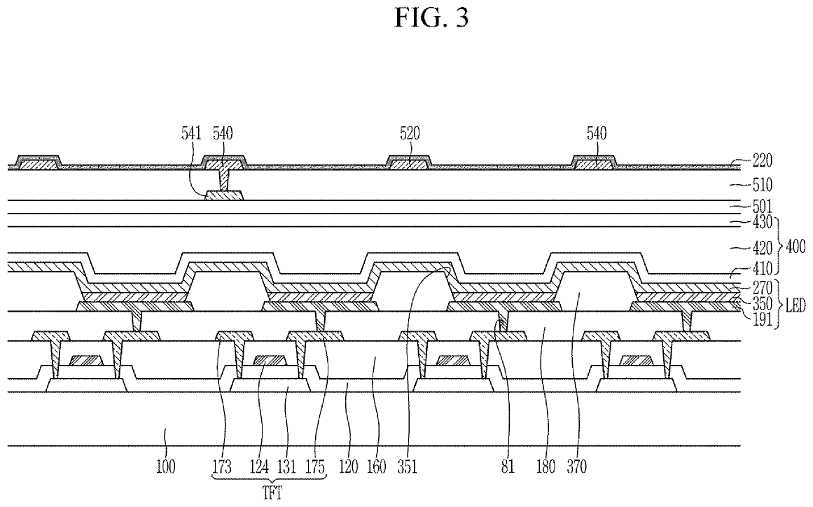

Hereinafter, referring to FIG. 3, the display device according to the embodiment will be described in more detail, while referring to a cross-sectional view in the display area DA.

FIG. 3 is a schematic cross-sectional view of a portion of the display area in the display device according to the embodiment.

As shown in FIG. 3, the display area DA of the display device according to the embodiment may include a substrate 100, a semiconductor 131, a transistor TFT that includes a gate electrode 124, a source electrode 173, and a drain electrode 175, a gate insulating layer 120, an interlayer insulating layer 160, a lower planarization layer 180, a pixel electrode 191, an emission layer 350, a partitioning wall 370, a common electrode 270, and an encapsulation layer 400. Here, the pixel electrode 191, the emission layer 350, and the common electrode 270 may form a light emitting diode LED.

The display device may further include the detection area TA that is disposed in an upper portion of the display area DA, and the detection area TA may include a detection insulation layer 510, detection electrodes 520 and 540, and a detection electrode connection portion 541. The display device may further include a light blocking member 220 that is disposed in an upper portion of the detection area TA.

The substrate 100 may include a material that has a rigid characteristic such as glass and the like and thus is not bendable, or may include a flexible material that is bendable such as plastic or a polyimide. Although it is not illustrated in FIG. 3, a lower buffer layer (not shown) or a barrier layer (not shown) may be further disposed on the substrate 100 to planarize the surface of the substrate 100 and prevent permeation of an impurity element. The barrier layer may be disposed on the substrate 100, and the buffer layer may be disposed on the barrier layer. The barrier layer may include an inorganic material, and for example, may include an inorganic insulating material such as a silicon nitride (SiNx), a silicon oxide (SiOx), a silicon oxynitride (SiOxNy), and the like. The barrier layer BA may be a single layer or a multiple layer of the above-stated material. The buffer layer may include an inorganic insulating material such as a silicon nitride (SiNx), a silicon oxide (SiOx), a silicon oxynitride (SiOxNy), and the like. The buffer layer may be a single layer or a multiple layer of the above-stated material.

The semiconductor 131 may be disposed on the substrate 100. The semiconductor 131 may include any one of an amorphous silicon, a polysilicon, and an oxide semiconductor. For example, the semiconductor 131 may include a low temperature polysilicon (LTPS), or a semiconductor oxide material that includes at least one of zinc (Zn), indium (In), gallium (Ga), tin (Sn), and a mixture thereof. For example, the semiconductor 131 may include indium-gallium-zinc oxide (IGZO). The semiconductor 131 may include a channel region, a source region, and a drain region that are distinguished depending on impurity doping. The source region and the drain region may have conductive characteristics corresponding to a conductor.

The gate insulating layer 120 may cover the semiconductor 131 and the substrate 100. The gate insulating layer 120 may include an inorganic insulating material such as a silicon nitride (SiNx), a silicon oxide (SiOx), a silicon oxynitride (SiOxNy), and the like. The gate insulating layer 120 may be a single-layered or multi-layered structure of the above-stated material.

The gate electrode 124 may be disposed on the gate insulating layer 120. The gate electrode 124 may include a metal or a metal alloy such as copper (Cu), molybdenum (Mo), aluminum (Al), silver (Ag), chromium (Cr), tantalum (Ta), and titanium (Ti). The gate electrode 124 may be formed of a single layer or multiple layers. A region of the semiconductor 131, overlapping the gate electrode 124 in a plan view, may be the channel region.

The interlayer insulating layer 160 may cover the gate electrode 124 and the gate insulating layer 120. The interlayer insulating layer 160 may include an inorganic insulating material such as a silicon nitride (SiNx), a silicon oxide (SiOx), a silicon oxynitride (SiOxNy), and the like. The interlayer insulating layer 160 may have a single layered or multiple layered structure.

The source electrode 173 and the drain electrode 175 may be disposed on the interlayer insulating layer 160. The source electrode 173 and the drain electrode 175 are respectively electrically connected with the source region and the drain region of the semiconductor 131 by openings that are respectively formed in the interlayer insulating layer 160 and the gate insulating layer 120. Accordingly, the semiconductor 131, the gate electrode 124, the source electrode 173, and the drain electrode 175 form a single transistor TFT. Depending on the embodiments, the transistor TFT may include only the source region and the drain region of the semiconductor 131 instead of including the source electrode 173 and the drain electrode 175.

The source electrode 173 and the drain electrode 175 may include a metal or a metal alloy of aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode 173 and drain electrode 175 may be formed of a single layer or multiple layers. Depending on the embodiments, the source electrode 173 and the drain electrode 175 may be formed of a triple layer including an upper layer, an intermediate layer, and a lower layer, the upper layer and the lower layer may include titanium (Ti), and the intermediate layer may include aluminum (Al).

The lower planarization layer 180 may be disposed on the source electrode 173 and the drain electrode 175. The lower planarization layer 180 covers the source electrode 173, the drain electrode 175, and the interlayer insulating layer 160. The lower planarization layer 180 serves to planarize the surface of the substrate 100 where the transistor TFT is provided, and may be an organic insulating layer including one or more materials selected from a group consisting of a polyimide, a polyamide, an acryl resin, benzocyclobutene, and a phenol resin.

The pixel electrode 191 may be disposed on the lower planarization layer 180. The pixel electrode 191 is also called an anode, and may be formed of a single layer including a transparent conductive oxide film and a metallic material, or multiple layers including them. The transparent conductive oxide layer may include an indium tin oxide (ITO), a poly-ITO, an indium zinc oxide (IZO), an indium gallium zinc oxide (IGZO), and an indium tin zinc oxide (ITZO). The metallic material may include silver (Ag), molybdenum (Mo), copper (Cu), gold (Au), and aluminum (Al).

The lower planarization layer 180 may include a via hole 81 (also called an opening) that exposes the drain electrode 175. The drain electrode 175 and the pixel electrode 191 may be physical and electrically connected with each other through the via hole 81 of the lower planarization layer 180. Accordingly, the pixel electrode 191 may receive an output current to be transmitted to an emission layer 350 from the drain electrode 175.

A partitioning wall 370 may be disposed on the pixel electrode 191 and the lower planarization layer 180. The partitioning wall 370 is also called a pixel defining layer (PDL), and includes a pixel opening 351 through which a part of the top surface of the pixel electrode 191 is exposed. The partitioning wall 370 may partition formation positions of the emission layer 350 such that the emission layer 350 may be disposed in the exposed portion of the top surface of the pixel electrode 191. The partitioning wall 370 may be an organic insulating layer that includes at least one material selected from a group consisting of a polyimide, a polyamide, an acryl resin, benzocyclobutene, and a phenol resin. Depending on the embodiments, the partitioning wall 370 may be provided as a black pixel defining layer BPDL including a black color pigment.

The emission layer 350 may be disposed in the pixel opening 351 partitioned by the partitioning wall 370. The emission layer 350 may include organic materials emitting red, green, and blue light. The emission layer 350 emitting red, green, and blue light may include a low molecular weight or high molecular weight organic material. In FIG. 3, the emission layer 350 is shown as a single layer, but substantially, an auxiliary layer such as an electron injection layer, an electron transport layer, a hole transport layer, and a hole injection layer may be included above and below the emission layer 350, and a hole injection layer and a hole transport layer may be disposed below the emission layer 350, while an electron transport layer and an electron injection layer may be disposed above the emission layer 350.

The common electrode 270 may be disposed on the partitioning wall 370 and the emission layer 350. The common electrode 270 is also called a cathode, and may be formed as a transparent conductive layer including an indium tin oxide (ITO), an indium zinc oxide (IZO), an indium gallium zinc oxide (IGZO), and an indium tin zinc oxide (ITZO). The common electrode 270 may have a translucent characteristic, and may form a micro-cavity with the pixel electrode 191. Due to the micro-cavity structure, the gap between the electrodes, and the characteristics of the electrodes, light with a specific wavelength may be emitted upward, and thus red, green, or blue may be displayed.

The encapsulation layer 400 may be disposed on the common electrode 270. The encapsulation layer 400 may include at least one inorganic layer and at least one organic layer. In the embodiment, the encapsulation layer 400 may include a first inorganic encapsulation layer 410, an organic encapsulation layer 420, and a second inorganic encapsulation layer 430. However, this is only an example, and the embodiments are not limited by the number of inorganic and organic layers forming the encapsulation layer 400. The first inorganic encapsulation layer 410, the organic encapsulation layer 420, and the second inorganic encapsulation layer 430 may be disposed in the display area DA and a part of the non-display area NA. Depending on the embodiments, the organic encapsulation layer 420 may be formed around the display area DA, and the first inorganic encapsulation layer 410 and the second inorganic encapsulation layer 430 may be formed up to the non-display area NA. The encapsulation layer 400 may protect the light emitting diode LED from moisture or oxygen that may be introduced from the outside, and one end of the first inorganic encapsulation layer 410 and one end of the second inorganic encapsulation layer 430 may directly contact each other.

A buffer layer 501 may be disposed on the encapsulation layer 400. The buffer layer 501 may be formed as an inorganic insulating layer, and an inorganic material included in the inorganic insulating layer may be at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride. Depending on the embodiments, the buffer layer 501 may be omitted.

The detection electrode connection portion 541, the detection insulation layer 510, and the detection electrodes 520 and 540 may be disposed on the buffer layer 501. The first detection electrode connection portion 521 or the second detection electrode connection portion 541 may be disposed in the same layer as the detection electrodes 520 and 540, and the other detection electrode connection portion may be disposed in a different layer from the detection electrodes 520 and 540. Hereinafter, it will be described that the second detection electrode connection portion 541 is disposed in a different layer from the detection electrodes 520 and 540.

The detection electrode connection portion 541, the detection insulation layer 510, and the detection electrodes 520 and 540 may form a detection sensor. The detection sensor may be classified into a resistive type, a capacitive type, an electro-magnetic type, and an optical type. In the embodiment, a capacitive type of sensor may be used as the detection sensor.

The detection electrode connection portion 541 may be disposed on the buffer layer 501, and the detection insulation layer 510 may be disposed on the buffer layer 501 and the second detection electrode connection portion 541. The detection insulation layer 510 may be an inorganic insulating layer, and depending on embodiments, an organic material may be included. The inorganic material may include at least one of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxide nitride. The organic material may include at least one of an acryl-based resin, a methacrylic resin, a polyisoprene, a vinyl-based resin, an epoxy-based resin, a urethane-based resin, a cellulose-based resin, and a perylene-based resin.

The detection electrodes 520 and 540 may be disposed on the detection insulation layer 510. The detection electrodes 520 and 540 may include first detection electrodes 520 and second detection electrodes 540. The first detection electrode 520 and the second detection electrode 540 may be electrically insulated from each other. The detection insulation layer 510 includes an opening that exposes the top surface of the second detection electrode connection portion 541, and the second detection electrode connection portion 541 is connected with the second detection electrode 540 through the opening of the detection insulation layer 510 and thus electrically connects two adjacent detection insulation layers 510. The first detection electrode connection portion 521 that connects the first detection electrodes 520 may be formed in the same layer as the first detection electrode 520 and the second detection electrode 540.

The detection electrodes 520 and 540 may include a highly conductive material. For example, the detection electrodes 520 and 540 may include a metal or a metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), and the like. The detection electrodes 520 and 540 may be formed as a single layer or multiple layers. The detection electrodes 520 and 540 include openings and thus light emitted from the light emitting diode LED may be emitted upward without interference. Depending on the embodiments, the detection electrodes 520 and 540 may be formed of a triple layer including an upper layer, an intermediate layer, and a lower layer, the upper layer and the lower layer may contain titanium (Ti), and the intermediate layer may contain aluminum (Al).

A light blocking member 220 may be disposed on the detection electrodes 520 and 540. The light blocking member 220 may be also disposed on the detection insulation layer 510. The light blocking member 220 may be disposed to overlap the detection electrodes 520 and 540, and may be disposed to overlap the emission layer 350 and the pixel electrode 191 as well. The light blocking member 220 may overlap the entire regions of the detection electrodes 520 and 540. The light blocking member 220 may overlap the entire region of the emission layer 350, and may overlap the entire region of the pixel electrode 191. The light blocking member 220 may be disposed on the entire substrate 100. The light blocking member 220 may be disposed in a region where light is emitted from a light emitting diode LED of each pixel and a boundary between the pixels. The light blocking member 220 may have a constant thickness. The light blocking member 220 may include an organic material including a black color pigment, or a mixture of the organic material including the black color pigment and an inorganic material. In other embodiments, an insulating layer may be further disposed between the detection electrodes 520 and 540 and the light blocking member 220.

Light may be incident into the display device from the outside, and when the external light is reflected from the display device, the light may be visible and the contrast ratio of the display device may be reduced. In the display device according to the embodiment, the light blocking member 220 is disposed on the entire substrate 100, and thus external light may be partially prevented from being incident into the display device. Although some external light may be incident into the display device by passing through the light blocking member 220 and thus may be reflected by the pixel electrode 191 and the like, the reflected light may not be visible from the outside of the display device because the light blocking member 220 may absorb the reflected light. The display device according to the embodiment may prevent the external light from being reflected and from being visible from the outside.

Since the light blocking member 220 is disposed on the detection electrodes 520 and 540, when there may be an external impact to the display device, the impact applied to the detection electrodes 520 and 540 or other electrode layers disposed below the detection electrodes 520 and 540 may be cushioned.

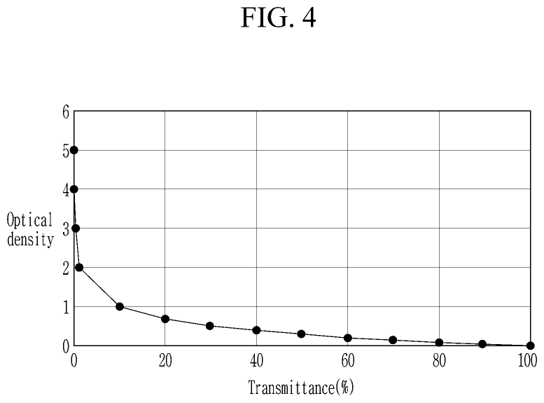

Hereinafter, referring to FIG. 4, a relationship between an optical density of the light blocking member and transmittance of the display device will be described.

FIG. 4 is a graph illustrating transmittance of the display device according to an optical density of the light blocking member.

As shown in FIG. 4, it may be determined that the transmittance of the display device is decreased as the optical density of the light blocking member is increased. The transmittance gradually decreases as the optical density of the light blocking member is increased to about 1 from about 0, and the transmittance may be close to about 0% when the optical density of the light blocking member is about 2 or more. In the FIG. 4, the transmittance refers to only transmittance of light incident from the outside when all the pixels of the display device are off. When the pixel of the display device is on as a reference, the transmittance of the display device may have a value close to about 0% when the optical density of the light blocking member is about 4.3 or higher.

Increasing the optical density of the light blocking member may increase a blocking rate of reflected light, but simultaneously the transmittance of the display device may be lowered. The transmittance of the display device may be increased when the optical density is lowered, but the blocking rate of the reflected light may be lowered. Thus, the optical density of the light blocking member may be appropriately selected when considering the transmittance of the display device and the blocking rate of reflected light together.

The optical density of the light blocking member may be determined by a thickness, concentration, and the like of the light blocking member. As the thickness of the light blocking member is increased, the optical density of the light blocking member may be increased. The optical density of the light blocking member may be increased as the concentration of the light blocking member is increased. For example, the light blocking member may have a predetermined optical density by increasing the concentration of the light blocking member and reducing the thickness of the light blocking member. The light blocking member may have a predetermined optical density by reducing the concentration of the light blocking member and increasing the thickness of the light blocking member. The thicker the thickness of the light blocking member, the greater the effect of the buffering action by the light blocking member.

Accordingly, it is possible to appropriately select the thickness and concentration of the light blocking member in consideration of the transmittance of the display device, the blocking rate of reflected light, and the buffer effect by the light blocking member.

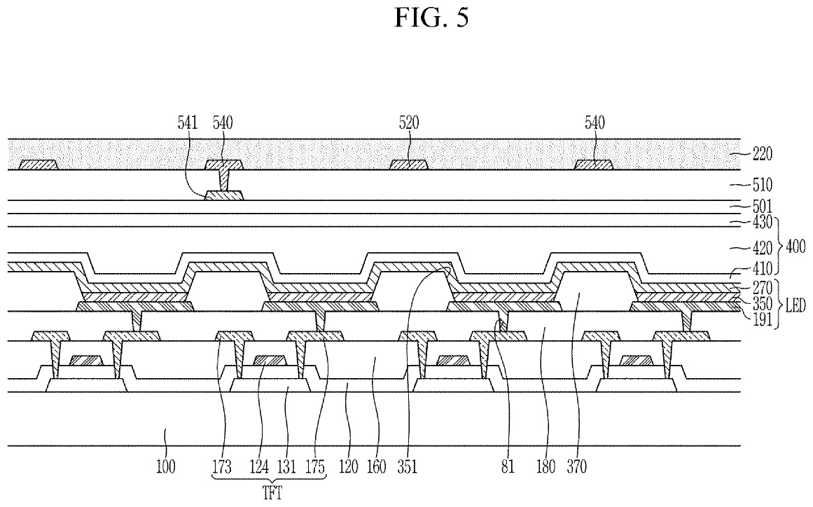

Referring to FIG. 5, a display device according to an embodiment will be described.

A display device according to an embodiment shown in FIG. 5 shares parts with the display device according to the embodiment shown in FIG. 1 to FIG. 4, and thus the description of same parts will not be repeated. The embodiment is different from the above-described embodiment in that the thickness of the light blocking member is increased, and this will be described in further detail.

FIG. 5 is a schematic cross-sectional view of a display device according to an embodiment.

As shown in FIG. 5, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. An encapsulation layer 400 may be disposed on a common electrode 270, and detection layers 520 and 540 may be disposed on the encapsulation layer 400. A light blocking member 220 may be disposed on the detection electrodes 520 and 540.

The light blocking member 220 may be disposed to overlap the detection electrodes 520 and 540, and to overlap the emission layer 350 and the pixel electrode 191. The light blocking member 220 may be disposed on the entire substrate 100. Light incident on the display device from the outside may be prevented from being reflected by the light blocking member 220 and any reflected external light may be prevented from being visible.

In the embodiment described in FIG. 3, the light blocking member 220 is thin and has a high concentration, and in the embodiment of FIG. 5, the light blocking member 220 is thick and has a low concentration. Optical density of the light blocking member 220 may be adjusted by changing the concentration and thickness of the light blocking member 220. The light blocking member of the embodiment in FIG. 3 and the light blocking member of the embodiment in FIG. 5 may have the same optical density, while having different concentrations and thicknesses. Since the light blocking member 220 according to the embodiment is thick, wires disposed below the light blocking member 220 may be more effectively protected from external impact. The impact resistance of the display device may be improved.

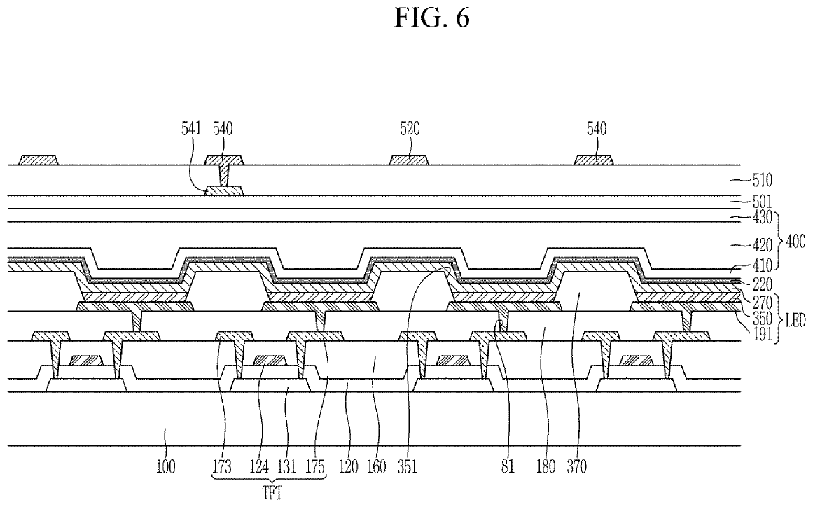

Referring to FIG. 6, a display device according to an embodiment will be described.

A display according to an embodiment shown in FIG. 6 shares parts with the display device according to the embodiment shown in FIG. 1 to FIG. 4, and therefore, the descriptions of the same parts will not be repeated. In the embodiment of FIG. 6, the position of the light blocking member is different from the embodiment of FIG. 3, and will be further described below.

FIG. 6 is a schematic cross-sectional view of a display device according to an embodiment.

As shown in FIG. 6, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. The encapsulation layer 400 may be disposed on the common electrode 270, and detection electrodes 520 and 540 may be disposed on the encapsulation layer 400.

The light blocking member 220 may be disposed between the common electrode 270 and the encapsulation layer 400. The light blocking member 220 may be disposed on the common electrode 270, and the encapsulation layer 400 may be disposed on the light blocking member 220. However, the position of the light blocking member 220 is not limited thereto, and in other embodiments, the position of the light blocking member 220 may be modified. For example, the light blocking member 220 may be disposed between a first inorganic encapsulation layer 410 and an organic encapsulation layer 420, which form the encapsulation layer 400.

The light blocking member 220 may be disposed to the detection electrodes 520 and 540 and overlap the emission layer 350 and the pixel electrode 191. The light blocking member 220 may be disposed on the entire substrate 100. The light blocking member 220 may prevent light incident on the display device from being reflected and being visible from the outside.

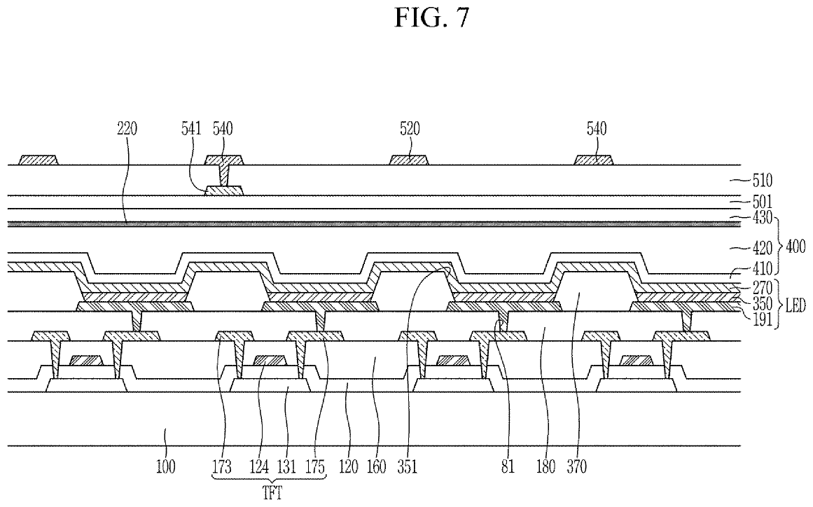

Referring to FIG. 7, a display device according to an embodiment will be described.

The display according to an embodiment shown in FIG. 7 shares parts with the display device according to the embodiment shown in FIG. 1 to FIG. 4, and therefore descriptions of the same parts will not be repeated. In the embodiment of FIG. 7, the position of the light blocking member 220 is different from the previous embodiments, and will be further described below.

FIG. 7 is a schematic cross-sectional view of a display device according to an embodiment.

As shown in FIG. 7, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. An encapsulation layer 400 may be disposed on the common electrode 270, and detection electrodes 520 and 540 may be disposed on the encapsulation layer 400.

The light blocking member 220 may be disposed in the encapsulation layer 400. The encapsulation layer 400 may include a first inorganic encapsulation layer 410, an organic encapsulation layer 420, and a second inorganic encapsulation layer 430. The light blocking member 220 may be disposed between the organic encapsulation layer 420 and the second inorganic encapsulation layer 430. The organic encapsulation layer 420 may be disposed on the first inorganic encapsulation layer 410, and the light blocking member 220 may be disposed on the organic encapsulation layer 420. The second inorganic encapsulation layer 430 may be disposed on the light blocking member 220.

The light blocking member 220 may be disposed to overlap the detection electrodes 520 and 540 and to overlap the emission layer 350 and the pixel electrode 191 as well. The light blocking member 220 may be disposed on the entire substrate 100. The light blocking member 220 may prevent light incident on the display device from the outside from being reflected and any reflected external light may be prevented from being visible from the outside.

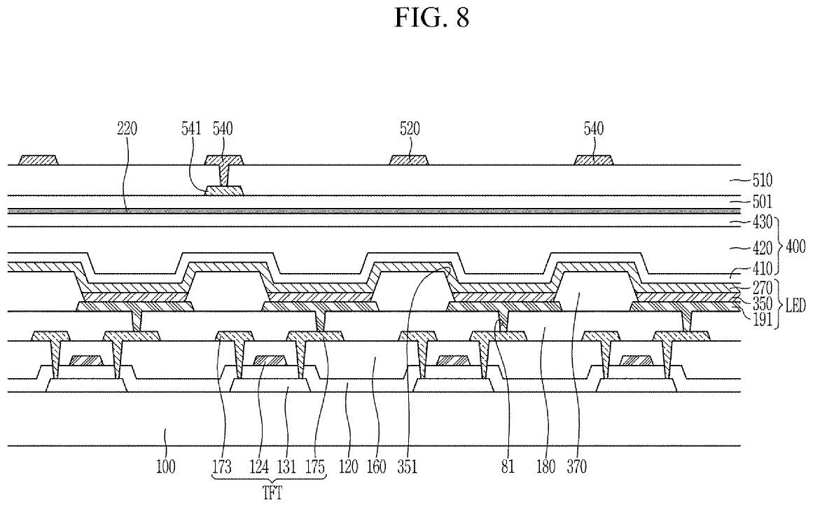

Referring to FIG. 8, a display device according to an embodiment will be described.

A display according to an embodiment shown in FIG. 8 shares parts with the display device according to the embodiment shown in FIG. 1 to FIG. 4, and therefore, the description of the same parts will not be repeated. In the embodiment of FIG. 8, the position of the light blocking member is different from the previous embodiments, and will be further described below.

FIG. 8 is a schematic cross-sectional view of a display device according to an embodiment.

As shown in FIG. 8, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. An encapsulation layer 400 may be disposed on the common electrode 270, and detection electrodes 520 and 540 may be disposed on the encapsulation layer 400.

The light blocking member 220 may be disposed between the encapsulation layer 400 and the detection electrodes 520 and 540. The light blocking member 220 may be disposed on the encapsulation layer 400, and the detection electrodes 520 and 540 may be disposed on the light blocking member 220. A buffer layer 501 may be disposed between the light blocking member 220 and the detection electrodes 520 and 540.

The light blocking member 220 may be disposed to overlap the detection electrodes 520 and 540 and the emission layer 350 and the pixel electrode 191 as well. The light blocking member 220 may be disposed on the entire substrate 100. The light blocking member 220 may prevent light incident on the display device from the outside from being reflected and any reflected external light may be prevented from being visible from the outside.

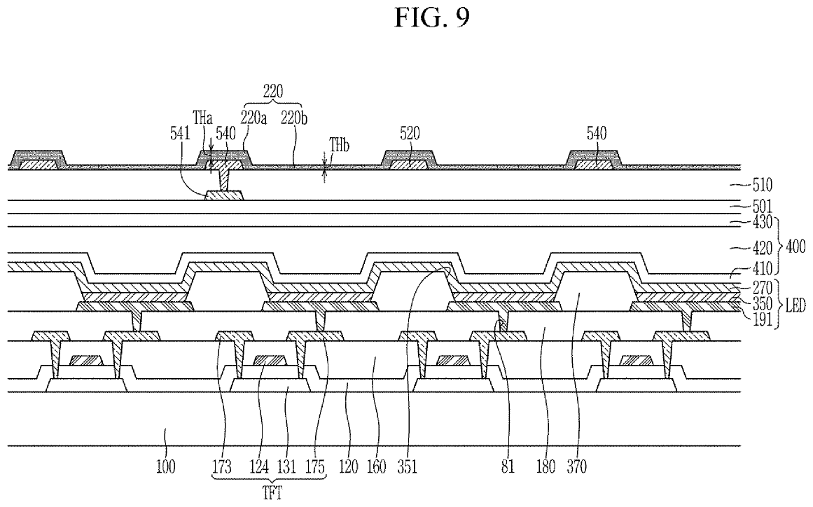

Referring to FIG. 9, a display device according to an embodiment will be described.

A display according to an embodiment shown in FIG. 9 shares parts with the display device according to the embodiment shown in FIG. 1 to FIG. 4, and therefore, the description of the same parts will not be repeated. The embodiment of FIG. 9 is different from the previous embodiments in that a thickness of a light blocking member may change depending on the position, and will be further described below.

FIG. 9 is a schematic cross-sectional view of a display device according to an embodiment.

A light blocking member 220 may be disposed to overlap detection electrodes 520 and 540 and overlap an emission layer 350 and a pixel electrode 191 as well. The light blocking member 220 may be disposed on the entire substrate 100. The light blocking member 220 may prevent light incident on the display device from the outside from being reflected and recognized.

The light blocking member 220 in the previous embodiment may have a constant thickness, and the light blocking member 220 in the embodiment may have a thickness that is changed depending on positions. The light blocking member 220 may include a first light blocking portion 220a having a first thickness THa and a second light blocking portion 220b having a second thickness THb. The first light blocking portion 220a may overlap the detection electrodes 520 and 540. The first light blocking portion 220a may overlap a portion between areas where light is emitted from a light emitting diode LED of each pixel at the boundaries of the pixels. The first light blocking portion 220a may not overlap the emission layer 350 and the pixel electrode 191. The second light blocking portion 220b may overlap the emission layer 350 and the pixel electrode 191. The second light blocking portion 220b may overlap a portion between areas where light is emitted from a light emitting diode LED of each pixel. The second light blocking portion 220b may not overlap the detection electrodes 520 and 540.

The first thickness THa of the light blocking member 220 may be thicker or greater than the second thickness THb of the second light blocking portion 220b. Concentration of the first light blocking portion 220a of the light blocking member 220 and concentration of the second light blocking portion 220b may be substantially equivalent to each other. In the light blocking member 220, the optical density of the first light blocking portion 220a may be higher than that of the second light blocking portion 220b. Since the second light blocking portion 220b of the light blocking member 220 has low optical density, transmittance of the display device may be improved while blocking light incident from the outside. Since the first light blocking portion 220a of the light blocking member 220 has high optical density, reflection of light incident from the outside may be effectively blocked. Since the first thickness THa of the first light blocking portion 220a of the light blocking member 220 is relatively thick, impact resistance may be more improved. The display device according to the embodiment may increase the transmittance of the display device, block reflection of external light, and improve impact resistance by providing a first thickness THa and a second thickness THb for the light blocking member 220.

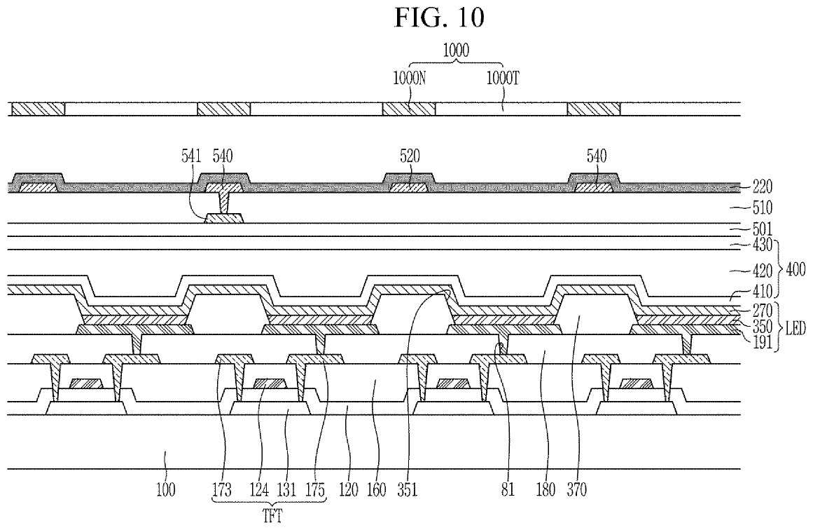

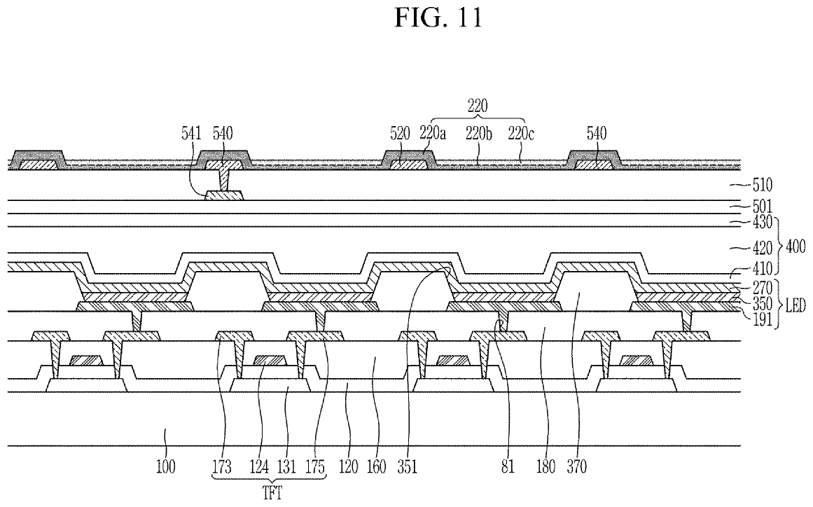

Hereinafter, a method for forming a light blocking member of a display device according to an embodiment shown in FIG. 9 will be described with reference to FIG. 10 and FIG. 11.

FIG. 10 and FIG. 11 show a process cross-sectional view of a method for forming a light blocking member of a display device according to an embodiment.

First, as shown in FIG. 10, a transistor TFT, a pixel electrode 191, an emission layer 350, and a common electrode 270 are sequentially formed on a substrate 100. An encapsulation layer 400 is formed on the common electrode 270, and detection electrodes 520 and 540 are formed on the encapsulation layer 400.

Subsequently, a light blocking material is applied on the detection electrodes 520 and 540 such that a light blocking member 220 is formed. The light blocking member 220 is formed on the entire substrate 100. A mask 1000 is placed on the light blocking member 220 and light is irradiated thereto such that a light process is carried out. The mask 1000 may include a transmitting portion 1000T and a non-transmitting portion 1000N. The mask 1000 may be a half-tone mask but the embodiments are not limited thereto. The transmitting portion 1000T of the mask 1000 may correspond to the emission layer 350 and the pixel electrode 191. The non-transmitting portion 1000N of the mask 1000 may correspond to the detection electrodes 520 and 540. Light irradiated to the mask 1000 may pass through the transmitting portion T of the mask 1000, and may not be transmitted through the non-transmitting portion 1000N and thus is blocked. The light passed through the transmitting portion 1000T of the mask 1000 may be transmitted to the light blocking member 220.

As shown in FIG. 11, a portion 220c of the light blocking member 220, corresponding to the transmitting portion 1000T of the mask 1000 is removed through an etching process such that the thickness of the light blocking member 220 may be reduced. Accordingly, a thickness of a first light blocking portion 220a of the light blocking member 220 and a thickness of a second light blocking portion 220b may be different from each other. The thickness of the first light blocking portion 220a of the light blocking member 220 is maintained, and the thickness of the second light blocking portion 220b is reduced. Thus, the thickness of the first light blocking portion 220a of the light blocking member 220 may be thicker or greater than that of the second light blocking portion 220b. The first light blocking portion 220a of the light blocking member 220 may overlap the detection electrodes 520 and 540, and the second light blocking portion 220b may overlap the emission layer 350 and the pixel electrode 191.

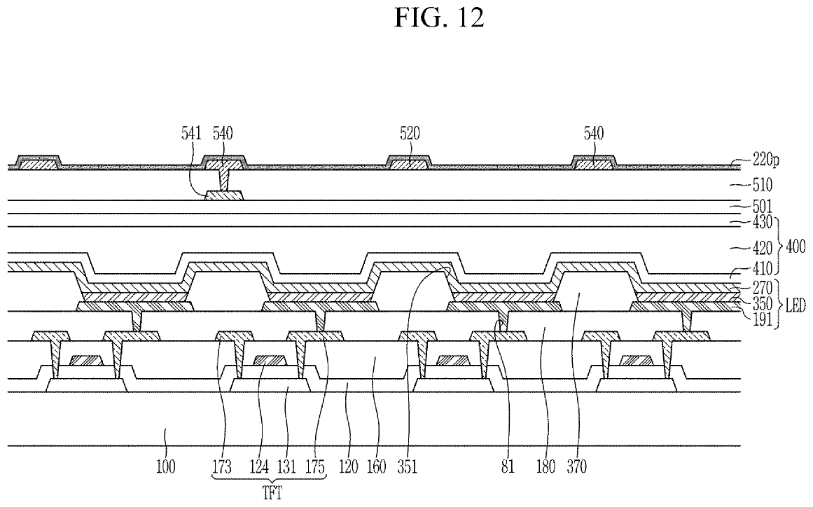

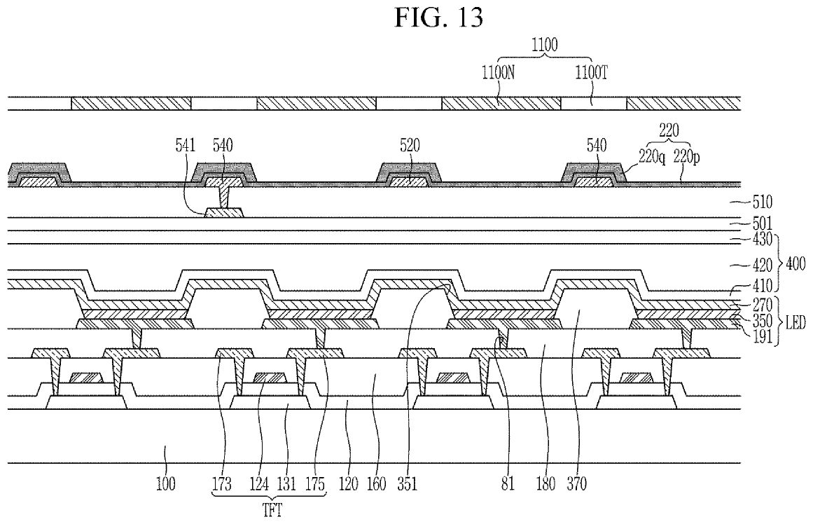

Hereinafter, another method for forming the light blocking member of the display device shown in the embodiment of FIG. 9 will be described with reference to FIG. 12 and FIG. 13.

FIG. 12 and FIG. 13 are process cross-sectional views of a method for forming the light blocking member of the display device according to the embodiment.

First, as shown in FIG. 12, the transistor TFT, the pixel electrode 191, the emission layer 350, and the common electrode 270 are sequentially formed on the substrate 100. The encapsulation layer 400 is formed on the common electrode 270, and the detection electrodes 520 and 540 are formed on the encapsulation layer 400.

Subsequently, a light blocking material is deposited to the detection electrodes 520 and 540 such that a first light blocking layer 220p is formed. The first light blocking layer 220p may be formed on the entire substrate 100. Thus, the first light blocking layer 220p may overlap the emission layer 350 and the pixel electrode 191, and may overlap detection electrodes 520 and 540 as well. The first light blocking layer 220p may overlap both a region where light is emitted from a light emitting element (LED) of each pixel and a boundary of pixels.

As shown in FIG. 13, a mask 1100 is placed on the first light blocking layer 220p, and then a light blocking material is deposited such that a second light blocking layer 220q is formed. The mask 1100 may include a transmitting portion 1100T and a non-transmitting portion 1100N. The mask 1100 may be a half-tone mask but the embodiments are not limited thereto. The transmitting portion 1100T of the mask 1100 may correspond to the detection electrodes 520 and 540. The non-transmitting portion 1100N of the mask 1100 may correspond to the emission layer 350 and the pixel electrode 191. A light blocking material may be deposited on a portion corresponding to the transmitting portion 1100T of the mask 1100, and the light blocking material may not be deposited on a portion corresponding to the non-transmitting portion 1100N of the mask 1100. The light blocking material may be partially deposited by using the mask 1100. The second light blocking layer 220q may overlap the detection electrodes 520 and 540, and may not overlap the emission layer 350 and the pixel electrode 191. However, a part of the edge of the second light blocking layer 220q may overlap the emission layer 350 or a part of the edge of the pixel electrode 191.

The first light blocking layer 220p and the second light blocking layer 220q may form the light blocking member 220. The first light blocking layer 220p may be disposed on the entire substrate 100, and the second light blocking layer 220q may be partially disposed on the substrate 100. Thus, the light blocking member 220 may have a thickness that changes according to positions. A portion of the light blocking member 220, in which the first light blocking layer 220p and the second light blocking layer 220q overlap, may be relatively thick. A portion where only the first light blocking layer 220p is deposited and the second light blocking layer 220q is not deposited may be relatively thin.

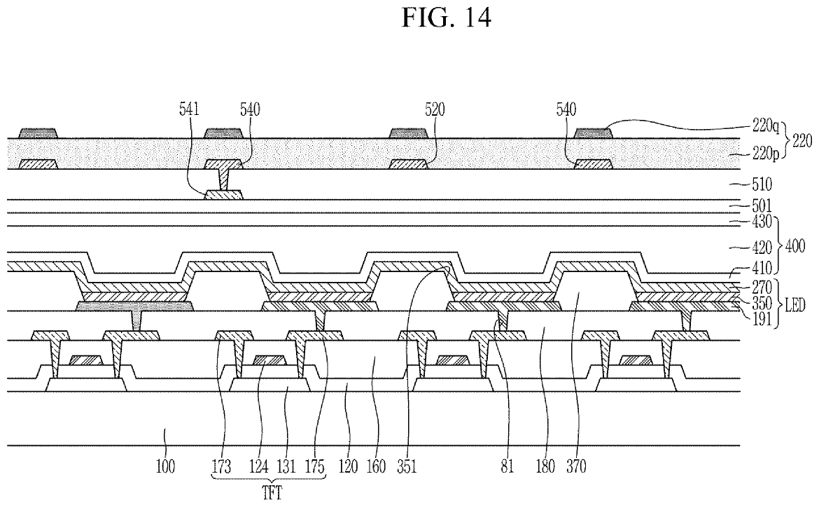

Referring to FIG. 14, a display device according to an embodiment will be described.

A display according to an embodiment shown in FIG. 14 is almost the same as the display device according to the embodiment shown in FIG. 9, and therefore, the description of the same parts will be omitted. The embodiment is different from the above-described embodiment in that a light blocking member has a different concentration depending on positions, and this will be described in further detail.

FIG. 14 is a schematic cross-sectional view of a display device according to an embodiment.

As shown in FIG. 14, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. An encapsulation layer 400 may be disposed on the common electrode 270, and detection electrodes 520 and 540 may be disposed on the encapsulation layer 400. A light blocking member 220 may be disposed on the detection electrodes 520 and 540.

The light blocking member 220 may be disposed to overlap the detection electrodes 520 and 540 and overlap the emission layer 350 and the pixel electrode 191 as well. The light blocking member 220 may be disposed on the entire substrate 100. Light incident on the display device from the outside be prevented from being reflected and recognized, by the light blocking member 220.

In the embodiment, the light blocking member 220 may be formed of a double layer. The light blocking member 220 may include a first light blocking layer 220p and a second light blocking layer 220q disposed on the first light blocking layer 220p. The first light blocking layer 220p may be disposed between the detection electrodes 520 and 540 and the second light blocking layer 220q. The first light blocking layer 220p may be disposed on the entire substrate 100. Thus, the first light blocking layer 220p may overlap the emission layer 350 and the pixel electrode 191, and may overlap the detection electrodes 520 and 540 as well. The first light blocking layer 220p may overlap both a region where light is emitted from a light emitting element (LED) of each pixel and a boundary of pixels. The second light blocking layer 220q may be disposed only in a partial region. The second light blocking layer 220q may overlap the detection electrodes 520 and 540, and may not overlap the emission layer 350 and the pixel electrode 191.

Concentration of the first light blocking layer 220p of the light blocking member 220 may be different from concentration of the second light blocking layer 220q. The concentration of the second light blocking layer 220q may be higher than that of the first light blocking layer 220p. A portion of the light blocking member 220, in which the emission layer 350 and the pixel electrode 191 overlap, is formed of only the first light blocking layer 220p. The concentration of the first light blocking layer 220p is lowered and the thickness of the first light blocking layer 220p is reduced such that reflection of external light may be blocked while maintaining transmittance of the display device, and impact resistance may be improved. A portion of the light blocking member 220, not overlapping the emission layer 350 and the pixel electrode 191, may include a first light blocking layer 220p and a second light blocking layer 220q. The portion is a region overlapping with wires, and even if the optical density of the light blocking member 220 is increased, the transmittance of the display device may not be affected. Therefore, it is possible to further block reflection of external light while maintaining the transmittance of the display device, and further improve the impact resistance. The display device according to the embodiment may increase the transmittance of the display device, block reflection of external light, and improve impact resistance by providing two levels of concentration and thickness for the light blocking member 220.

In the above, it was described that the second light blocking layer 220q having a relatively high concentration is positioned on the first light blocking layer 220p having a relatively low concentration, but is not limited thereto. On the contrary, the first light blocking layer 220p having a relatively low concentration may be positioned on the second light blocking layer 220q having a relatively high concentration. The first light blocking layer 220p may be formed to cover the entire second light blocking layer 220q. The first light blocking layer 220p may cover the top and side surfaces of the second light blocking layer 220q.

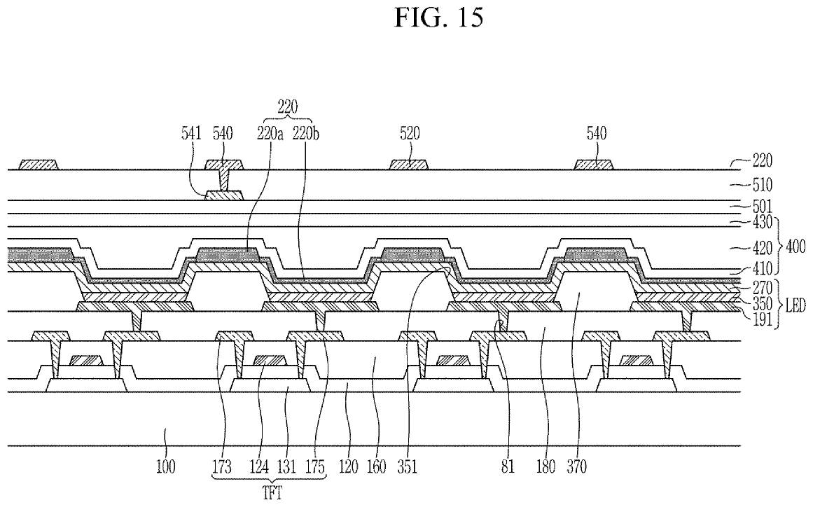

A display device according to an embodiment will be described with reference to FIG. 15

A display device according to an embodiment shown in FIG. 15 is almost the same as the display device according to the embodiment shown in FIG. 9, and therefore, the description of the same parts is omitted. The embodiment is different from the previous embodiment in a position of a light blocking member, and this will be described in further detail hereinafter.

FIG. 15 is a schematic cross-sectional view of a display device according to an embodiment.

As shown in FIG. 15, a display device according to an embodiment includes a substrate 100, a transistor TFT, a pixel electrode 191, an emission layer 350, and a common electrode 270. The pixel electrode 191, the emission layer 350, and the common electrode 270 may form a light emitting diode LED. An encapsulation layer 400 may be disposed on the common electrode 270, and detection electrodes 520 and 540 may be disposed on the encapsulation layer 400.

A light blocking member 220 may be disposed between the common electrode 270 and the encapsulation layer 400. The light blocking member 220 may be disposed on the common electrode 270, and the encapsulation layer 400 may be disposed on the light blocking member 220. However, the position of the light blocking member 220 is not limited thereto, and in other embodiments, the position of the light blocking member 220 may be modified. For example, the light blocking member 220 may be disposed between a first inorganic encapsulation layer 410 and an organic encapsulation layer 420, which form the encapsulation layer 400.

The light blocking member 220 may be disposed to overlap the detection electrodes 520 and 540 and overlap the emission layer 350 and the pixel electrode 191 as well. The light blocking member 220 may be disposed on the entire substrate 100. Light incident on the display device from the outside may be prevented from being reflected by the light blocking member 220, and any reflected light may be prevented from being visible from the outside.

The thickness of the light blocking member 220 may be different depending on positions. The light blocking member 220 may include a first light blocking portion 220a and a second light blocking portion 220b. The first light blocking portion 220a may be or greater than the second light blocking portion 220b. The first light blocking layer 220p may overlap both a region where light is emitted from a light emitting element (LED) of each pixel and a boundary of pixels. The first light blocking portion 220a may not overlap the emission layer 350 and the pixel electrode 191. The second light blocking portion 220b may overlap the emission layer 350 and the pixel electrode 191. The second light blocking portion 220b may overlap a region where light is emitted from a light emitting diode LED of each pixel. The second light blocking portion 220b may not overlap the detection electrodes 520 and 540. The display device according to the embodiment may increase the transmittance of the display device, block reflection of external light, and improve impact resistance by providing at least two levels of thickness for the light blocking member 220

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a transistor disposed on a substrate;
a pixel electrode electrically connected to the transistor;
an emission layer disposed on the pixel electrode;
a common electrode disposed on the emission layer; and
a light blocking member disposed on the common electrode,
wherein the light blocking member overlaps the entire emission layer.

2. The display device of claim 1, wherein the light blocking member is disposed on an entire area of the substrate.

3. The display device of claim 2, wherein the light blocking member overlaps the pixel electrode.

4. The display device of claim 1, further comprising:
an encapsulation layer disposed on the common electrode; and
a detection electrode disposed on the encapsulation layer.

5. The display device of claim 4, wherein
the light blocking member is disposed on the detection electrode, and
the light blocking member overlaps the detection electrode.

6. The display device of claim 4, wherein
the light blocking member is disposed between the common electrode and the encapsulation layer, and
the light blocking member overlaps the detection electrode.

7. The display device of claim 4, wherein the light blocking member is disposed in the encapsulation layer.

8. The display device of claim 7, wherein
the encapsulation layer comprises a plurality of layers, and
the light blocking member is disposed between the plurality of layers of the encapsulation layer.

9. The display device of claim 4, wherein the light blocking member is disposed between the encapsulation layer and the detection electrode.

10. The display device of claim 1, wherein
the light blocking member comprises:
a first light blocking portion having a first thickness; and
a second light blocking portion having a second thickness, and
the first thickness is greater than the second thickness.

11. The display device of claim 10, wherein
the display device comprises a plurality of pixels,
the first light blocking portion overlaps a boundary of the plurality of pixels, and
the second light blocking portion overlaps the plurality of pixels.

12. The display device of claim 11, wherein
the first light blocking portion does not overlap the emission layer, and
the second light blocking portion overlaps the emission layer.

13. The display device of claim 10, further comprising:
an encapsulation layer disposed on the common electrode; and
a detection electrode disposed on the encapsulation layer.

14. The display device of claim 13, wherein
the light blocking member is disposed on the detection electrode,
the first light blocking portion overlaps the detection electrode, and
the second light blocking portion overlaps the pixel electrode.

15. The display device of claim 14, wherein
each of the first light blocking portion and the second light blocking portion of the light blocking member is formed of a single layer, and
the first light blocking portion and the second light blocking portion are formed by using a mask.

16. The display device of claim 14, wherein
the first light blocking portion of the light blocking member is formed as multiple layers, and
the second light blocking portion of the light blocking member is formed as a single layer.

17. The display device of claim 13, wherein
the light blocking member is disposed between the common electrode and the encapsulation layer,
the first light blocking portion overlaps the detection electrode, and
the second light blocking portion overlaps the pixel electrode.

18. The display device of claim 1, wherein the light blocking member comprises:
a first light blocking layer; and
a second light blocking layer disposed on the first light blocking layer.

19. The display device of claim 18, wherein a concentration of the second light blocking layer is higher than a concentration of the first light blocking layer.

20. The display device of claim 19, wherein
the first light blocking layer is disposed on an entire area of the substrate, and
the second light blocking layer does not overlap the emission layer.
